(19) United States
(12) Patent Application Publication
(10) Pub. No.: US 2025/0372551 A1
(43) Pub. Date: Dec. 4, 2025

(54) SEMICONDUCTOR STRUCTURE AND METHOD OF MANUFACTURE

(71) Applicant: Taiwan Semiconductor Manufacturing Company Limited, Hsin-Chu (TW)

(72) Inventors: Hsi-Cheng HSU, Taichung City (TW); Jui-Chun WENG, Taipei City (TW); Chih-Chung LEE, Tainan City (TW); Ji-Hong CHIANG, Changhua City (TW); Kuo-Hao LEE, Hsinchu (TW)

(21) Appl. No.: 18/732,957

(22) Filed: Jun. 4, 2024

(51) Int. Cl. H01L 23/00; H01L 21/02; H01L 21/027; H01L 21/3065; H01L 21/3213; H01L 25/065

(52) U.S. Cl. CPC H01L 24/05; H01L 21/0262; H01L 21/0273; H01L 21/3065; H01L 21/32139; H01L 24/13; H01L 25/0655; H01L 2224/05009; H01L 2224/05025; H01L 2224/13007; H01L 2224/13025; H01L 2924/01013; H01L 2924/01029; H01L 2924/13067; H01L 2924/182

(57) ABSTRACT

In some embodiments, a semiconductor structure includes a semiconductor layer, a micro-electromechanical systems structure defined in the semiconductor layer, and a metallization structure bonded to the semiconductor layer. The metallization structure includes a sensing pad, a first barrier layer comprising a first material under the sensing pad, a conductive pad, and a second barrier layer under the conductive pad. The second barrier layer includes a first layer comprising the first material and a second layer comprising a second material different than the first material over the first layer. The second barrier layer is compressively stressed, and hillocks are defined in the conductive pad.

### BACKGROUND

Micro-electromechanical systems (MEMS) combine mechanical and electronic components on a semiconductor structure. A MEMS structure can be used as a sensor, such as a pressure sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-20 illustrate a semiconductor device at various stages of fabrication, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

According to some embodiments, a microelectromechanical systems (MEMS) device is formed. The MEMS device is bonded to a device wafer to create a sealed cavity surrounding the MEMS device. Hillocks are formed on surfaces of vias and dummy pads that interface with the MEMS device to protect sensing pads from damage. The dummy pad may horizontally overlap with the moveable MEMS element proximate the sensing pad such that the moveable MEMS element would contact the dummy pad prior to contacting the sensing pad. The hillocks may be formed in layers of the vias and dummy pads comprising aluminum copper with underlying barrier layers comprising different materials that induce compressive stress. Thermal processing of AlCu in the presence of compressive stress results in the formation of triangular or trapezoidal shaped crystalline structures that form the hillocks. The hillocks increase the surface roughness. If the movement of a movable element in the MEMS device is sufficient to cause the movable element to contact one of the vias or the dummy pads, the hillocks reduce the likelihood that the movable element will adhere and potentially damage the MEMS device. The hillocks may also be formed on bond pads that bond the MEMS device to the device wafer to enhance the bond quality, thereby relaxing the applied pressure requirements for the bonding process and reducing the likelihood of warping or wafer breakage.

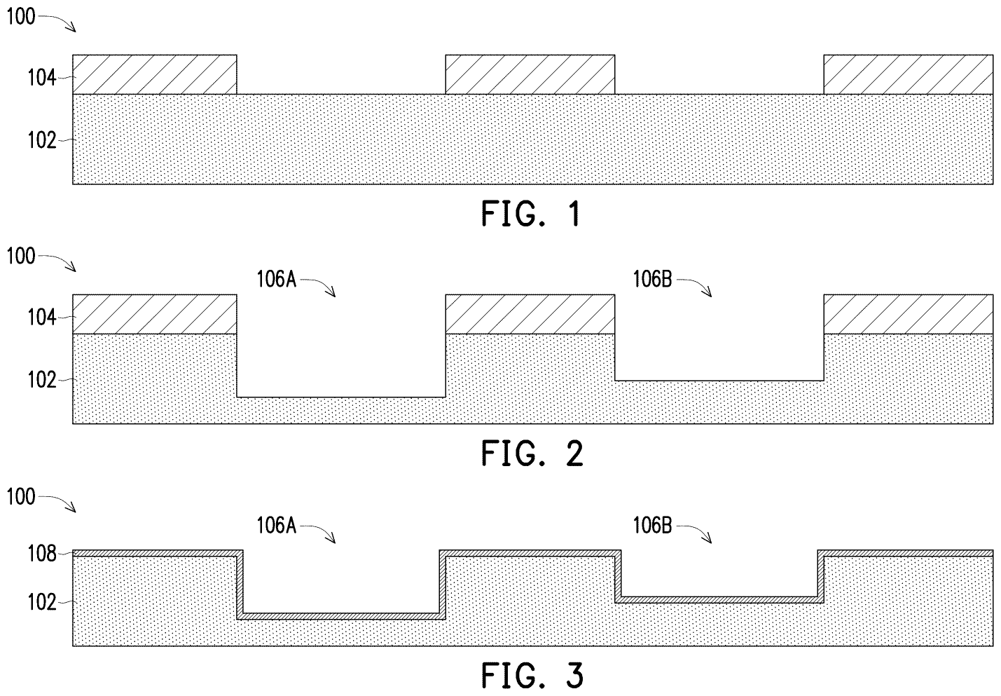

FIGS. 1-20 illustrate a semiconductor structure 100 at various stages of fabrication, in accordance with some embodiments. FIGS. 1-20 illustrate cross-section views of the semiconductor structure 100 at various stages of fabrication. In some embodiments, the semiconductor structure 100 is a MEMS structure. The semiconductor structure 100 includes a semiconductor layer 102 with a patterned mask 104 formed over the semiconductor layer 102. The semiconductor layer 102 comprises at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, and InP, a silicon-on-insulator (SOI) structure, a wafer, or a die formed from a wafer. In some embodiments, the semiconductor layer 102 comprises at least one of crystalline silicon or other suitable materials. The semiconductor layer 102 may be a silicon-on-insulator (SOI) substrate comprising a layer of a semiconductor material (e.g., silicon, germanium, or the like) formed over an insulator layer (e.g., buried oxide or the like), which is formed in a silicon substrate. Other substrates that may be used include multi-layered substrates, gradient substrates, hybrid orientation substrates, the like, or a combination thereof. Other structures and/or configurations of the semiconductor layer 102 are within the scope of the present disclosure.

The patterned mask 104 may comprise a single layer, such as photoresist, or a plurality of individually formed layers that together form a mask stack. In some embodiments, the patterned mask 104 comprises at least one of a hard mask layer, a bottom antireflective coating (BARC) layer, an organic planarization layer (OPL), or a photoresist layer. The hard mask layer is formed by at least one of physical vapor deposition (PVD) (e.g., sputtering and/or evaporation), chemical vapor deposition (CVD) (e.g., low pressure CVD (LPCVD), ultrahigh vacuum CVD (UHVCVD), reduced pressure CVD (RPCVD), plasma-enhanced CVD (PECVD), and/or atmospheric pressure CVD (APCVD)), spin on, growth, or other suitable techniques. In some embodiments, the hard mask layer comprises at least one of silicon and oxygen, silicon and nitrogen, nitrogen, silicon (e.g., polycrystalline silicon), or other suitable materials. In some embodiments, the BARC layer is a polymer layer that is applied using a spin coating process. In some embodiments, the OPL comprises a photo-sensitive organic polymer that is applied using a spin coating process. In some embodiments, the OPL comprises a dielectric layer. In some embodiments, the photoresist layer is formed by at least one of spinning, spray coating, or other suitable techniques. The photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist. One or more etchants have a selectivity such that the one or more etchants remove or etch away one or more layers exposed or not covered by the photoresist at a greater rate than the one or more etchants remove or etch away the photoresist. Accordingly, an opening in the photoresist allows the one or more etchants to form a corresponding opening in the one or more layers under the photoresist, and thereby transfer a pattern in the photoresist to the one or more layers under the photoresist. The photoresist is stripped or washed away after the pattern transfer. The layers of the mask stack are patterned to form the patterned mask 104. In some embodiments, the photoresist layer is exposed using a radiation source and a reticle to define a pattern in the photoresist layer, and portions of the photoresist layer are removed to define a patterned photoresist layer. The underlying OPL, BARC layer, and hard mask layer are etched using the patterned photoresist layer as a template to form the patterned mask 104 and expose portions of the semiconductor layer 102 under the patterned mask 104. Other structures and configurations of the patterned mask 104 within the scope of the present disclosure.

Referring to FIG. 2, recesses 106A, 106B are formed in the semiconductor layer 102, in accordance with some embodiments. The recesses 106A, 106B may be formed by performing an etch process using the patterned mask 104 as an etch template. The etch process may be a timed etch process. In some embodiments, the recesses 106A, 106B have different depths. An additional mask, such as a photoresist mask, may be formed in the recess 106B to facilitate additional etching to deepen the recess 106A.

Referring to FIG. 3, the patterned mask 104 is removed and a bonding layer 108 is formed over the semiconductor layer 102, in accordance with some embodiments. The bonding layer 108 may comprise silicon dioxide. The bonding layer 108 provides an interface for bonding another semiconductor wafer.

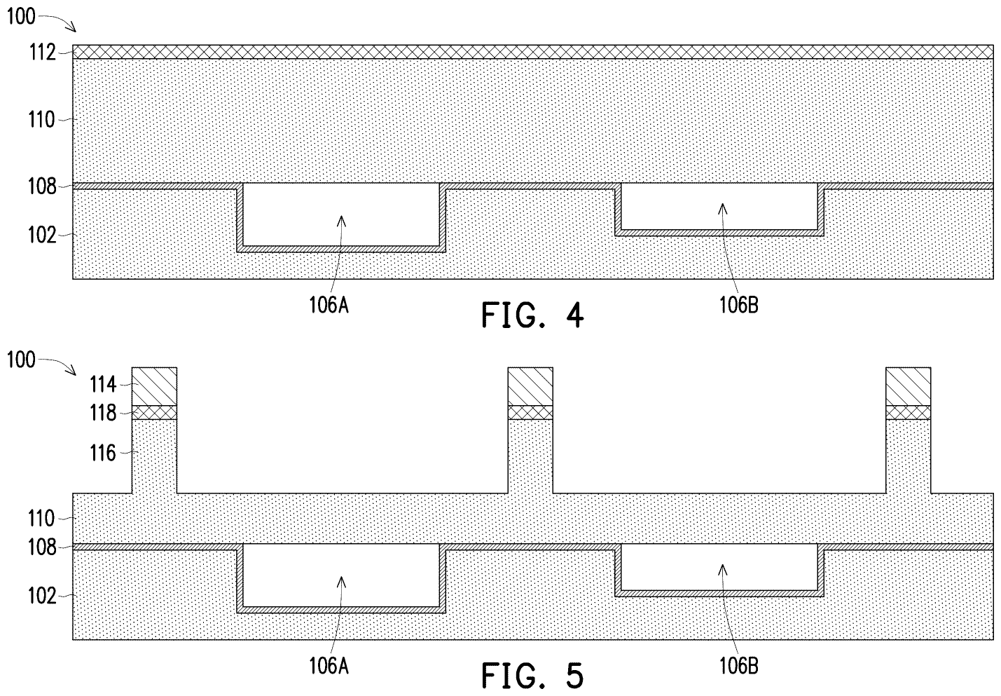

Referring to FIG. 4, a semiconductor layer 110 with a bond pad layer 112 is bonded to the bonding layer 108, in accordance with some embodiments. The semiconductor layer 110 does not fill the recesses 106A, 106B. The semiconductor layer 110 may be provided as a separate semiconductor wafer or a die formed from a semiconductor wafer. The semiconductor layer 110 may include at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, or InP. During the bonding process to attach the semiconductor layer 110 to the bonding layer 108, heat and/or pressure may be applied to the semiconductor layer 110 causing a bond to be formed between the semiconductor layer 110 and the bonding layer 108. Other substrates that may be used for the semiconductor layer 110 include multi-layered substrates, gradient substrates, hybrid orientation substrates, the like, or a combination thereof. Other structures and/or configurations of the semiconductor layer 110 are within the scope of the present disclosure.

In some embodiments, the bond pad layer 112 comprises germanium, a eutectic alloy of germanium, such as aluminum germanium (AlGe), or some other suitable material. A eutectic material is an alloy having a temperature where the constituents of the alloy melt at the same temperature and at a temperature lower than the melting point of any of its constituents. The bond pad layer 112 may be formed by using a PVD process (e.g., sputtering) with a germanium or aluminum germanium target and an inert ion, such as argon, as the sputtering element. The bond pad layer 112 may be formed prior to or after bonding the semiconductor layer 110 is bonded to the bonding layer 108.

Referring to FIG. 5, a patterned mask 114 is formed over the semiconductor layer, 110, stand-off features 116 are formed in the semiconductor layer 110, and bond pads 118 are formed in the bond pad layer 112, in accordance with some embodiments. The patterned mask 114 may be a photoresist mask or a stack of mask layers including at least one of a hard mask layer, a BARC layer, an OPL, or a photoresist layer comprising materials and formed as described herein. The stand-off features 116 and bond pads 118 may be formed by performing an etch process using the patterned mask 114 as an etch template to remove portions of the semiconductor layer 110 and the bond pad layer 112. The etch process may be a timed etch process. In some embodiments, the stand-off features 116 may have any closed shape when viewed from above such as a circular shape, a rectangular shape, or some other shape. The stand-off features 116 may define a bond ring for subsequent bonding of the MEMS structure to a device wafer.

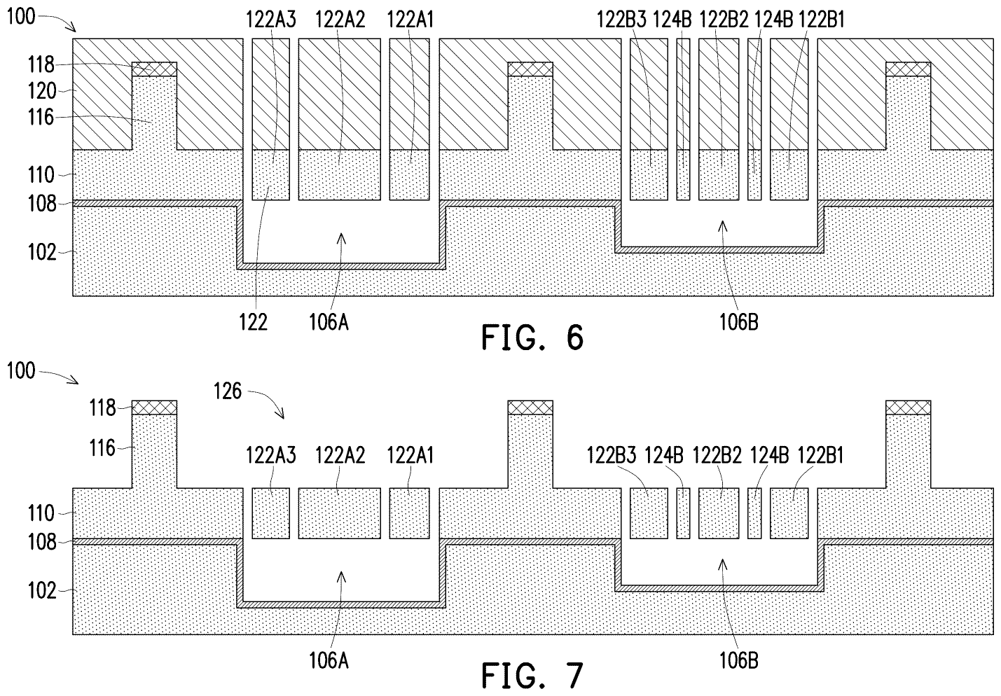

Referring to FIG. 6 the patterned mask 114 is removed, a patterned mask 120 is formed over the semiconductor layer 110, the bond pads 118, and the stand-off features 116, and the semiconductor layer 110 is patterned to form movable MEMS elements 122A1, 122A2, 122A3, 122B1, 122B2, 122B3 and stationary MEMS elements 124B, in accordance with some embodiments. The patterned mask 120 may be a photoresist mask or some other suitable mask stack. In some embodiments, an etch process is performed in the presence of the patterned mask 120 to form the movable MEMS elements 122A1, 122A2, 122A3, 122B1, 122B2, 122B3 and the stationary MEMS elements 124B. The etch process may be a timed etch process.

Referring to FIG. 7, the patterned mask 120 is removed, in accordance with some embodiments. The semiconductor layers 102, 110, the stand-off features 116, the movable MEMS elements 122A1, 122A2, 122A3, 122B1, 122B2, 122B3, and the stationary MEMS elements 124B define a MEMS structure 126.

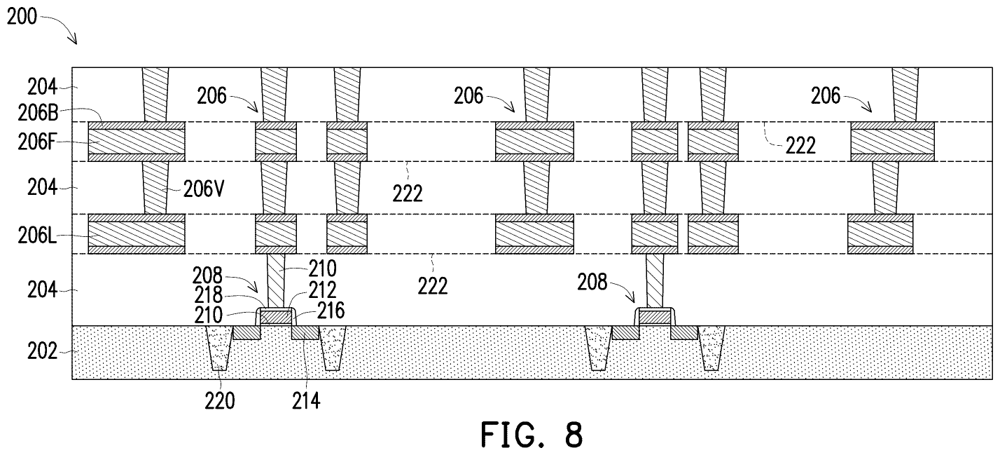

Referring to FIG. 8, a cross-section view of a device die 200 is provided, in accordance with some embodiments. According to some embodiments, the device die 200 comprises a substrate layer 202, interlayer dielectric layers 204, interconnect structures 206, and devices 208 formed over or within the substrate layer 202. In some embodiments, the devices 208 each comprise a gate dielectric layer 210 a gate electrode 212, source/drain regions 214, a sidewall spacer 216, a gate cap layer 218, etc. According to some embodiments, the gate dielectric layer 210, and the gate electrode 212 are formed using a gate replacement process. A sacrificial gate structure comprising a sacrificial gate dielectric layer, a sacrificial gate electrode layer, such as a polysilicon layer, and a hard mask layer are formed. In some embodiments, a patterning process is performed to pattern the hard mask layer corresponding to a pattern of gate structures to be formed, and an etch process is performed using the patterned hard mask layer to etch the sacrificial gate electrode layer and the sacrificial gate dielectric layer to define the sacrificial gate structure. In some embodiments, remaining portions of the hard mask layer form a cap layer over the portions of the sacrificial gate electrode layer remaining after the etch process. The sacrificial gate structure is later replaced with a replacement gate dielectric layer, such as the gate dielectric layer 210 and a replacement gate electrode, such as the gate electrode 212.

In some embodiments, the gate dielectric layer 210 comprises a high-k dielectric material. As used herein, the term “high-k dielectric” refers to the material having a dielectric constant, k, greater than or equal to about 3.9, which is the k value of SiO₂. The high-k dielectric material may be any suitable material. Examples of the high-k dielectric material include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2. In some embodiments, the gate dielectric layer 210 comprises a native oxide layer formed by exposure of the substrate layer 202 to oxygen at various points in the process flow, causing the formation of silicon dioxide on exposed surfaces. In some embodiments, an additional layer of dielectric material, such as silicon dioxide, a high-k dielectric material, or other suitable material, is formed over the native oxide to form the gate dielectric layer 210.

In some embodiments, the gate electrode 212 comprises a barrier layer, one or more work function material layers, a seed layer, a metal fill layer, or other suitable layers. In some embodiments, the metal fill layer comprises tungsten, aluminum, copper, cobalt, or other suitable material. In some embodiments, the gate dielectric layer 210 and the one or more layers that comprise the gate electrode 212 are deposited by at least one of atomic layer deposition (ALD), PVD, CVD, LPCVD, PECVD, atomic layer CVD (ALCVD), UHVCVD, RPCVD, molecular beam epitaxy (MBE), or other suitable techniques. In some embodiments, the gate electrode 212 is recessed and the gate cap layer 218 is formed in the recess.

In some embodiments, the sidewall spacer 216 is formed adjacent the gate dielectric layer 210 and the gate electrode 212. In some embodiments, the sidewall spacer 216 is formed by depositing a spacer layer over the sacrificial gate structure and performing an anisotropic etch process to remove horizontal portions of the spacer layer. In some embodiments, the sidewall spacer 216 comprises silicon nitride or other suitable materials.

In some embodiments, the source/drain regions 214 are formed in the substrate layer 202 after forming the sacrificial gate structure. For example, in some embodiments, portions of the substrate layer 202 are doped through an implantation process to form the source/drain regions 214. In some embodiments, an etch process is performed to recess the substrate layer 202 adjacent the sidewall spacer 216, and an epitaxial growth process is performed to form the source/drain regions 214.

In an embodiment, one or more shallow trench isolation (STI) structures 220 are formed within the substrate layer 202. In some embodiments, the STI structures 220 are formed by forming at least one mask layer over the substrate layer 202. In some embodiments, the at least one mask layer comprises a layer of oxide material over the substrate layer 202 and a layer of nitride material over the layer of oxide material, and/or one or more other suitable layers. At least some of the at least one mask layer is removed to define an etch mask for use as a template to etch the substrate layer 202 to form trenches. A dielectric material is formed in the trenches to define the STI structures 220. In some embodiments, the STI structures 220 include multiple layers, such as an oxide liner, a nitride liner formed over the oxide liner, an oxide fill material formed over the nitride liner, and/or other suitable materials. Other structures and/or configurations of the STI structures 220 are within the scope of the present disclosure.

In some embodiments, the devices 208 are formed using the same materials and layer thicknesses. In some embodiments, different materials and/or thicknesses may be used due to the different voltage domains. For example, the material and/or thickness of the gate dielectric layers 210 may differ from one another. Although the devices 208 are illustrated as being adjacent one other, in some embodiments, the devices 208 are formed in different regions. For example, if the gate dielectric layers 210 vary in thickness or material, the differing devices 208 may be formed in different regions. In some embodiments, the materials of the gate electrode 212 may also differ. Other structures and configurations of the devices 208 are within the scope of the present disclosure. For example, the devices 208 may be fin field-effect transistor (finFET) devices, nanosheet devices, nanowire devices, or some other suitable type of device.

The interlayer dielectric layers 204 are formed over the devices 208. In some embodiments, one of the interlayer dielectric layers 204 is formed prior to forming the replacement gate structures, if applicable. In some embodiments, the interlayer dielectric layers 204 comprise silicon dioxide or a low-k dielectric material. In some embodiments, the interlayer dielectric layers 204 comprises one or more layers of low-k dielectric material. Low-k dielectric materials have a k value lower than about 3.9. In some embodiments, the material for the interlayer dielectric layers 204 comprise at least one of Si, O, C, or H, such as SiCOH, SiOC, oxygen-doped SiC (ODC), nitrogen-doped SiC (NDC), plasma-enhanced oxide (PEOX), or other suitable materials. A low-k dielectric material is, in some embodiments, further characterized or classified as ultra low-k (ULK), extra low-k (ELK), or extreme low-k (XLK), where the classification is generally based upon the k value. For example, ULK generally refers to materials with a k value of between about 2.7 to about 2.4, ELK generally refers to materials with a k value of between about 2.3 to about 2.0, and XLK generally refers to materials with a k value of less than about 2.0. Organic material, such as polymers, may be used for the interlayer dielectric layer 204. In some embodiments, the interlayer dielectric layer 204 comprises one or more layers of a carbon-containing material, organo-silicate glass, a porogen-containing material, or combinations thereof. The interlayer dielectric layers 204 comprises nitrogen in some embodiments. In some embodiments, the interlayer dielectric layers 204 are formed by using, for example, at least one of CVD, PECVD, LPCVD, ALCVD, a spin-on technology, or some other suitable process.

In some embodiments, the interlayer dielectric layers 204 and interconnect structures 206 form a metallization structure with multiple metallization layer to interconnect the devices 208. The number of metallization layers may vary. The interconnect structures 206 may include via features 206V and line features 206L. The interconnect structures 206 are formed in any number of ways, such as by a single damascene process, a dual damascene process, a trench silicide process, or some other suitable process. In some embodiments, the interconnect structures 206 contact the gate electrodes 212 and additional contacts (not shown) are formed to contact the source/drain regions 214 in different positions along the axial lengths of the devices 208, such as into or out of the page. In some embodiments, the interconnect structures 206 comprise a barrier layer, a seed layer, a metal fill layer, or other suitable layers. For example, the line features 206L may include upper and lower barrier layers 206B, each comprising a titanium layer and a titanium nitride layer over the titanium layer, and a metal fill layer 206F. Barrier materials may also include tantalum, tantalum nitride, cobalt, or other suitable barrier materials. In some embodiments, the metal fill layer 206F comprises aluminum copper, tungsten, aluminum, copper, cobalt, or other suitable material. The via features 206V may comprise tungsten or other suitable material. Any number of metallization layers are contemplated. In some embodiments, different metallization layers are separated by etch stop layers 222 to allow etch control for forming various interconnect structures 206 embedded in the interlayer dielectric layers 204. The etch stop layers 222 comprise a dielectric material having a different etch selectivity from the interlayer dielectric layers 204. In some embodiments, at least one of the etch stop layers 222 comprises SiN, SiCN, SiCO, CN, etc., alone or in combination. The etch stop layers 222 are formed in any number of ways, such as by thermal growth, chemical growth, ALD, CVD, PECVD, or some other suitable process.

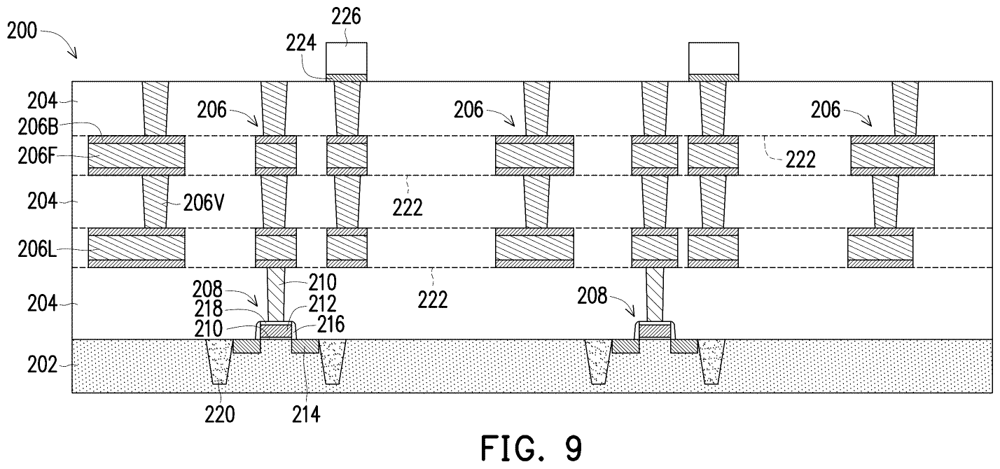

Referring to FIG. 9, a barrier layer 224 is formed over the uppermost interlayer dielectric layer 204 and the interconnect structures 206, a patterned mask 226 is formed over the barrier layer 224, and the barrier layer 224 is patterned, in accordance with some embodiments. The barrier layer 224 may comprise titanium. The barrier layer 224 may be formed using a PVD process (e.g., sputtering). The patterned mask 226 may be a photoresist mask or a stack of mask layers including at least one of a hard mask layer, a BARC layer, an OPL, or a photoresist layer comprising materials and formed as described herein. The barrier layer 224 may be patterned by performing an etch process using the patterned mask 226 as an etch template to remove portions of the barrier layer 224 exposed by the patterned mask 226.

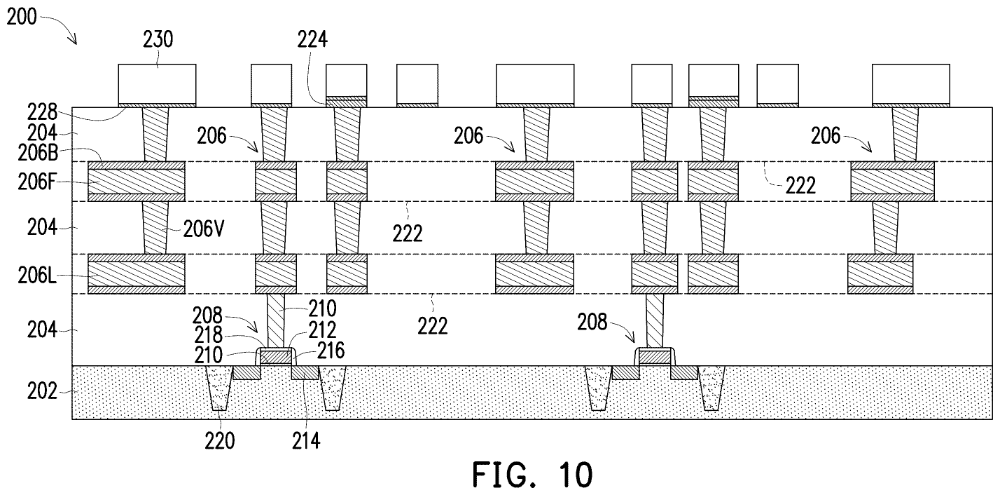

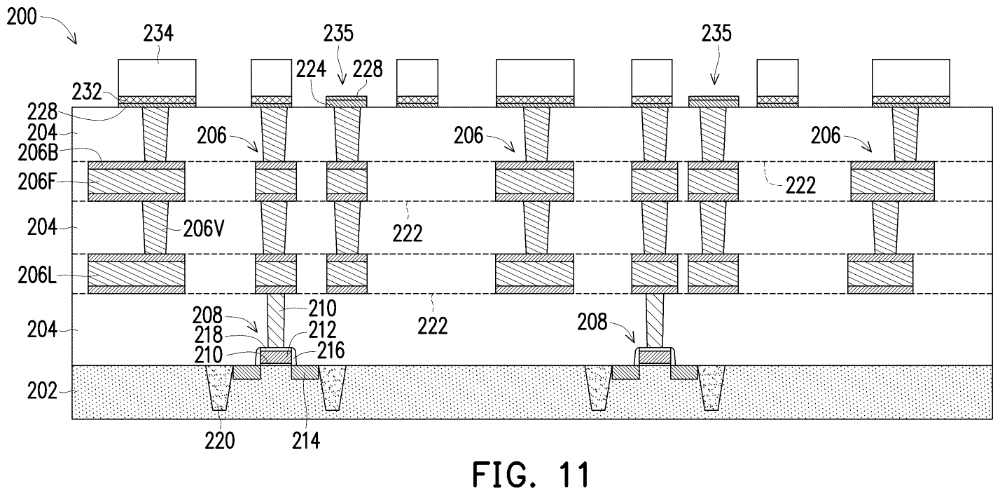

Referring to FIG. 10, the patterned mask 226 is removed, a barrier layer 228 is formed over the uppermost interlayer dielectric layer 204 and the barrier layer 224, a patterned mask 230 is formed over the barrier layer 228, and the barrier layer 228 is patterned, in accordance with some embodiments. The barrier layer 228 may comprise titanium. The barrier layer 228 may be formed using a PVD process (e.g., sputtering). The patterned mask 230 may be a photoresist mask or a stack of mask layers including at least one of a hard mask layer, a BARC layer, an OPL, or a photoresist layer comprising materials and formed as described herein. The barrier layer 228 may be patterned by performing an etch process using the patterned mask 230 as an etch template to remove portions of the barrier layer 228 exposed by the patterned mask 230.

Referring to FIG. 11, the patterned mask 230 is removed, a barrier layer 232 is formed over the uppermost interlayer dielectric layer 204 and the barrier layer 228, a patterned mask 234 is formed over the barrier layer 232, and the barrier layer 232 is patterned, in accordance with some embodiments. The barrier layer 232 may comprise titanium nitride. The barrier layer 232 may be formed using a PVD process (e.g., sputtering). The patterned mask 234 may be a photoresist mask or a stack of mask layers including at least one of a hard mask layer, a BARC layer, an OPL, or a photoresist layer comprising materials and formed as described herein. The barrier layer 232 may be patterned by performing an etch process using the patterned mask 234 as an etch template to remove portions of the barrier layer 232 exposed by the patterned mask 234. The barrier layer 232 is removed over the stack including the barrier layers 224, 228 in sensing pad regions 235.

In some embodiments, the combined thicknesses of the barrier layers 224, 228 is substantially the same as the combined thicknesses of the barrier layers 228, 232. The combined thicknesses may range from about 300 Å to 700 Å. In one example, the thicknesses of the barrier layers 224, 232 is about 500 Å and the thickness of the barrier layer 228 is about 125 Å, for a combined thickness of about 625 Å. The barrier layers 206B may have a construction similar to the barrier layers 228, 232 in terms of material and thickness.

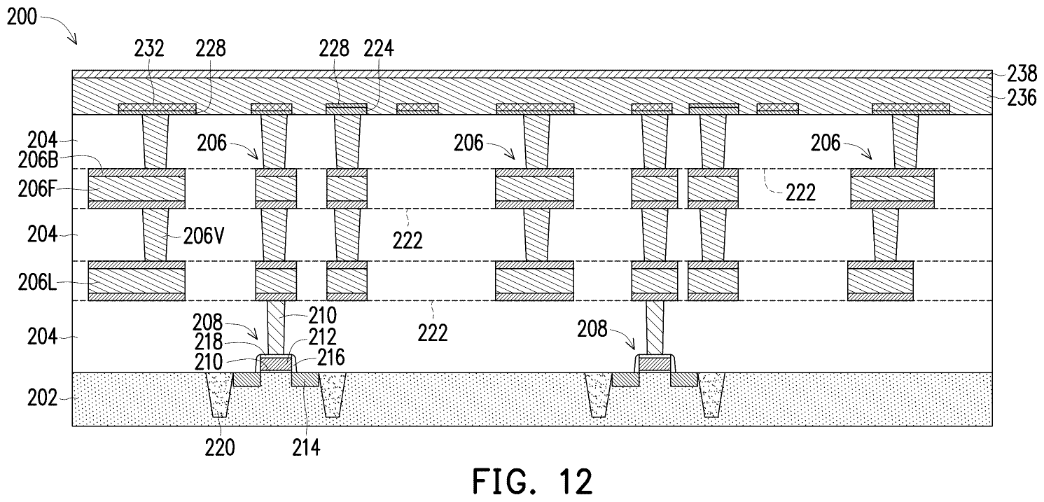

Referring to FIG. 12, the patterned mask 234 is removed, a metal fill layer 236 is formed over the uppermost interlayer dielectric layer 204 and the barrier layers 228, 232, and a barrier layer 238 is formed over the metal fill layer 236, in accordance with some embodiments. The metal fill layer 236 is a conductive layer. The metal fill layer 236 may comprise aluminum copper, and the barrier layer 238 may comprise a titanium layer and a titanium nitride layer over the titanium layer (e.g. similar to the barrier layers 228, 232 in terms of material and thickness). The metal fill layer 236 and the barrier layer 238 may be formed using PVD processes (e.g., sputtering).

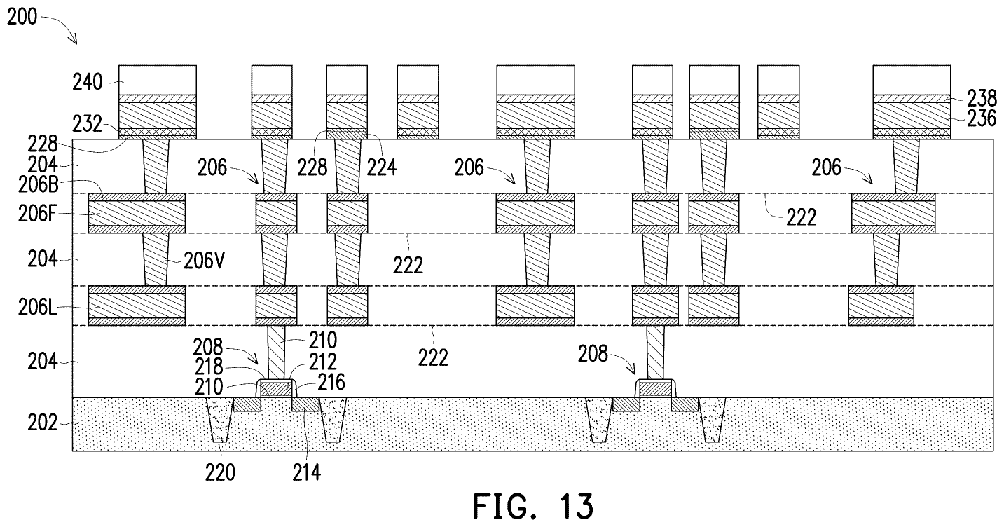

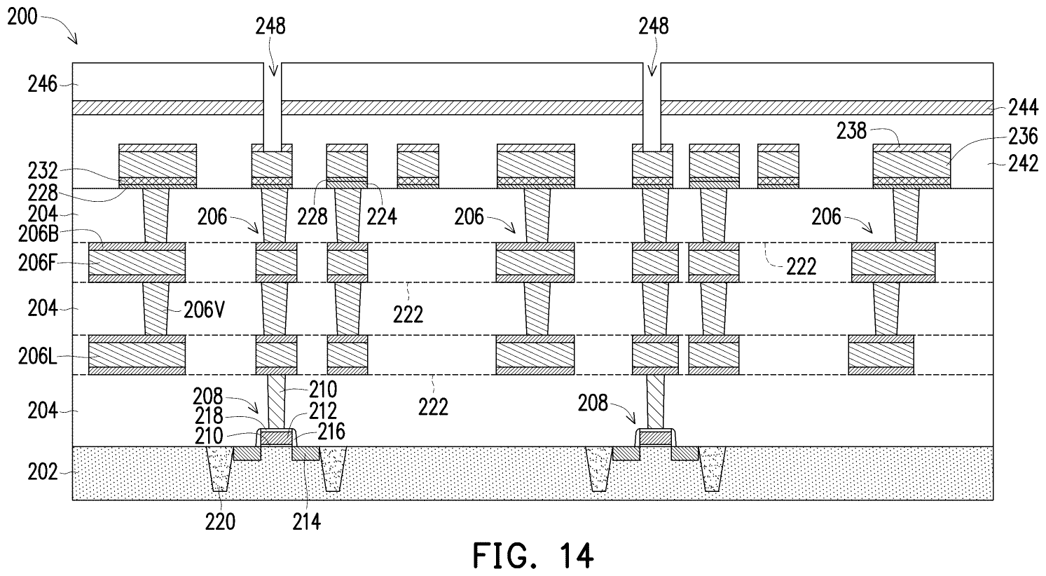

Referring to FIG. 13, a patterned mask 240 is formed over the barrier layer 238 and the barrier layer 238 and the metal fill layer 236 are patterned, in accordance with some embodiments. The patterned mask 240 may be a photoresist mask or a stack of mask layers including at least one of a hard mask layer, a BARC layer, an OPL, or a photoresist layer comprising materials and formed as described herein. The barrier layer 238 and the metal fill layer 236 may be patterned by performing an etch process using the patterned mask 240 as an etch template to remove portions of the barrier layer 238 and the metal fill layer 236 exposed by the patterned mask 234. Different etch chemistries may be used for the different materials removed.

Referring to FIG. 14, the patterned mask 240 is removed, passivation layers 242, 244 are formed over the uppermost interlayer dielectric layer 204 and the barrier layer 238, a patterned mask 246 is formed over the passivation layer 244, and the passivation layers 242, 244 and the barrier layer 238 are patterned to form via openings 248, in accordance with some embodiments. In some embodiments, the passivation layer 242 comprises silicon dioxide or a low-k dielectric material, and the passivation layer 244 comprises silicon nitride. The passivation layers 242, 244 are formed by using, for example, at least one of CVD, PECVD, LPCVD, ALCVD, a spin-on technology, or some other suitable process. The patterned mask 246 may be a photoresist mask or a stack of mask layers including at least one of a hard mask layer, a BARC layer, an OPL, or a photoresist layer comprising materials and formed as described herein. The passivation layers 242, 244 the barrier layer 238 may be patterned by performing an etch process using the patterned mask 246 as an etch template to remove portions of the passivation layers 242, 244 the barrier layer 238 exposed by the patterned mask 246. Different etch chemistries may be used for the different materials removed.

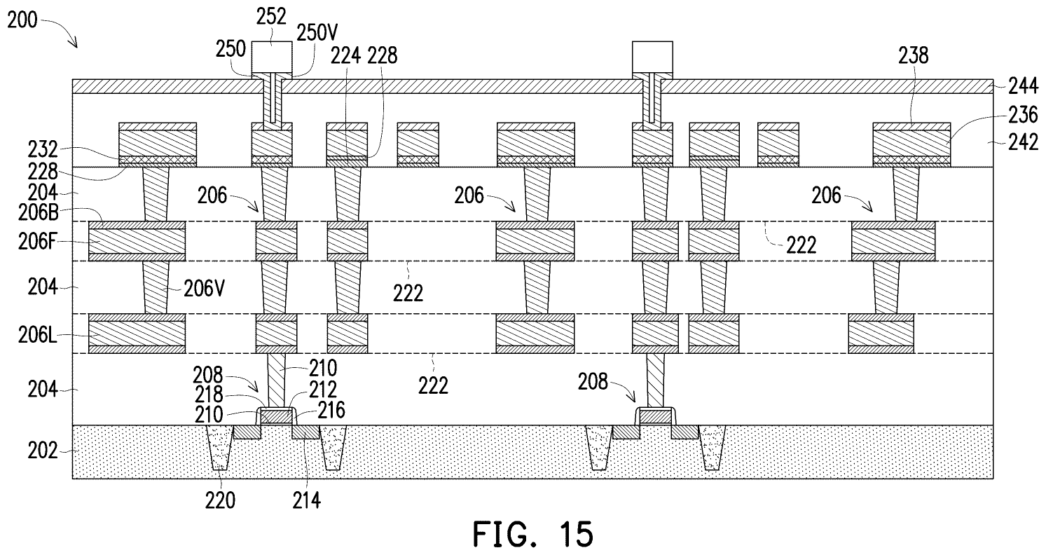

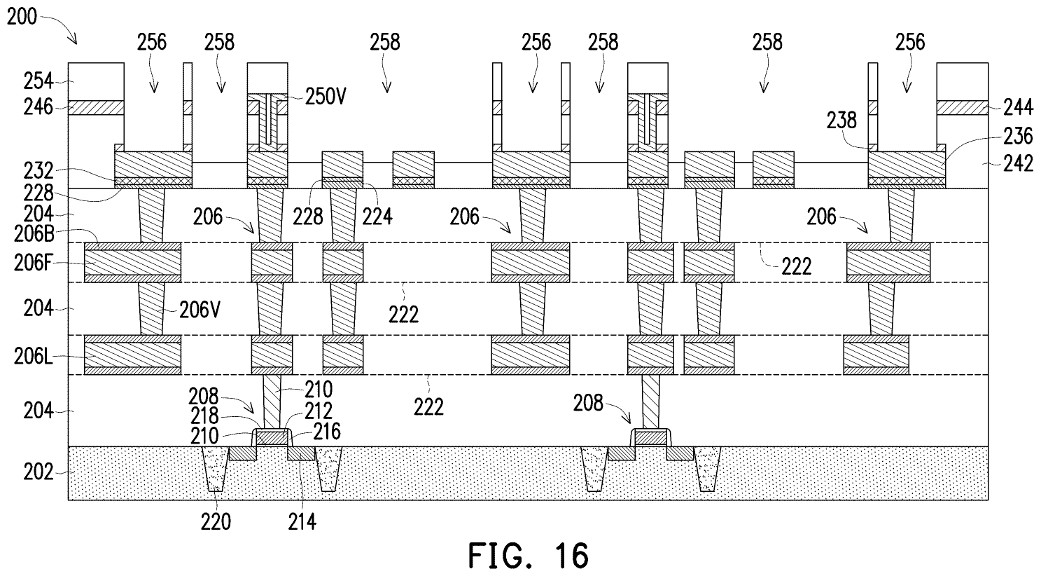

Referring to FIG. 15, the patterned mask 246 is removed, a conductive layer 250 is formed over the passivation layer 244 and in the via openings 248, a patterned mask 252 is formed over the conductive layer 250, and the conductive layer 250 is patterned to form vias 250V, in accordance with some embodiments. The conductive layer 250 may comprise aluminum copper. The conductive layer 250 may be formed using PVD processes (e.g., sputtering). The patterned mask 252 may be a photoresist mask or a stack of mask layers including at least one of a hard mask layer, a BARC layer, an OPL, or a photoresist layer comprising materials and formed as described herein. The conductive layer 250 may be patterned by performing an etch process using the patterned mask 252 as an etch template to remove portions of the conductive layer 250 exposed by the patterned mask 252 to form the vias 250V.

Referring to FIG. 16, the patterned mask 252 is removed, a patterned mask 254 is formed over the passivation layer 244 and the vias 250V, and the passivation layers 242, 244 and the barrier layer 238 are patterned to form openings 256, 258, in accordance with some embodiments. The patterned mask 254 may be a photoresist mask or a stack of mask layers including at least one of a hard mask layer, a BARC layer, an OPL, or a photoresist layer comprising materials and formed as described herein. The passivation layers 242, 244 and the barrier layer 238 may be patterned by performing an etch process using the patterned mask 254 as an etch template to remove portions of the passivation layers 242, 244 and the barrier layer 238 exposed by the patterned mask 254 to form the openings 256, 258. The provide bonding sites for the stand-off features 116 of the MEMS structure 126, and the openings 258 are part of the sensing cavity of the MEMS structure 126. In some embodiments, the passivation layer 242 is recessed in the openings 258 to expose portions of the metal fill layer 236.

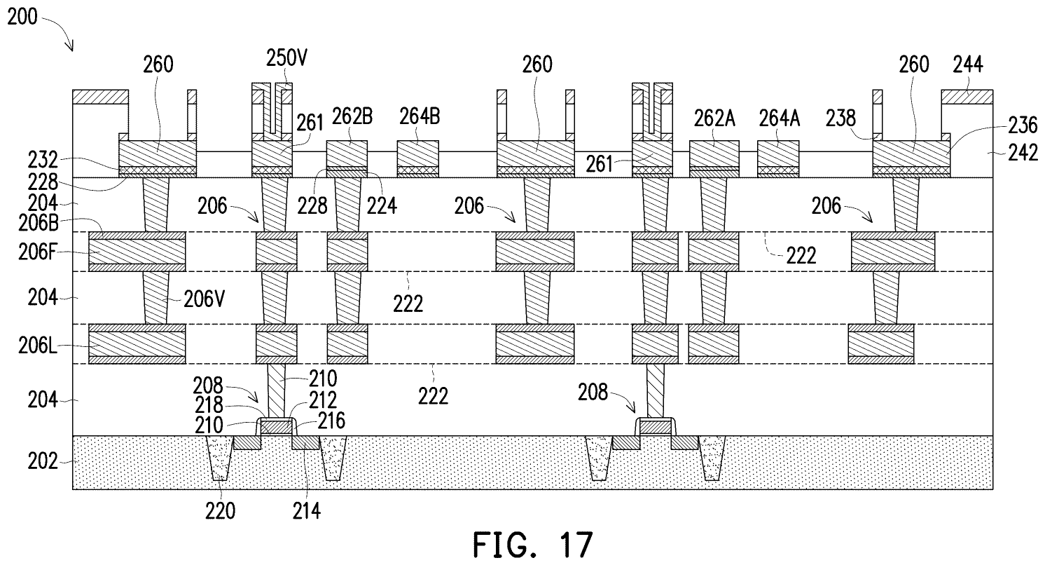

Referring to FIG. 17, the patterned mask 254 is removed, in accordance with some embodiments. The exposed portions of the metal fill layer 236 define bond pads 260, base pads 261, sensing pads 262A, 262B, and dummy pads 264A, 264B. The vias 250V are formed over the base pads 261.

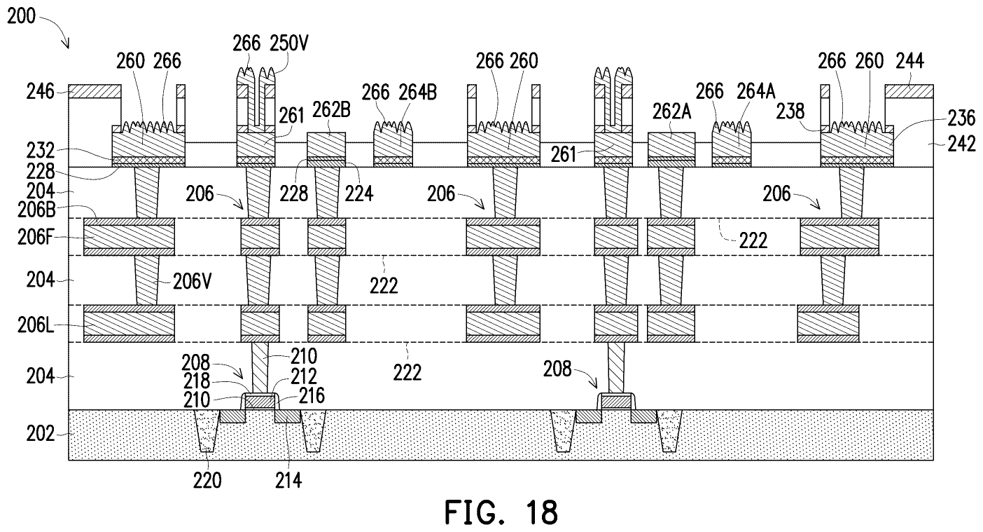

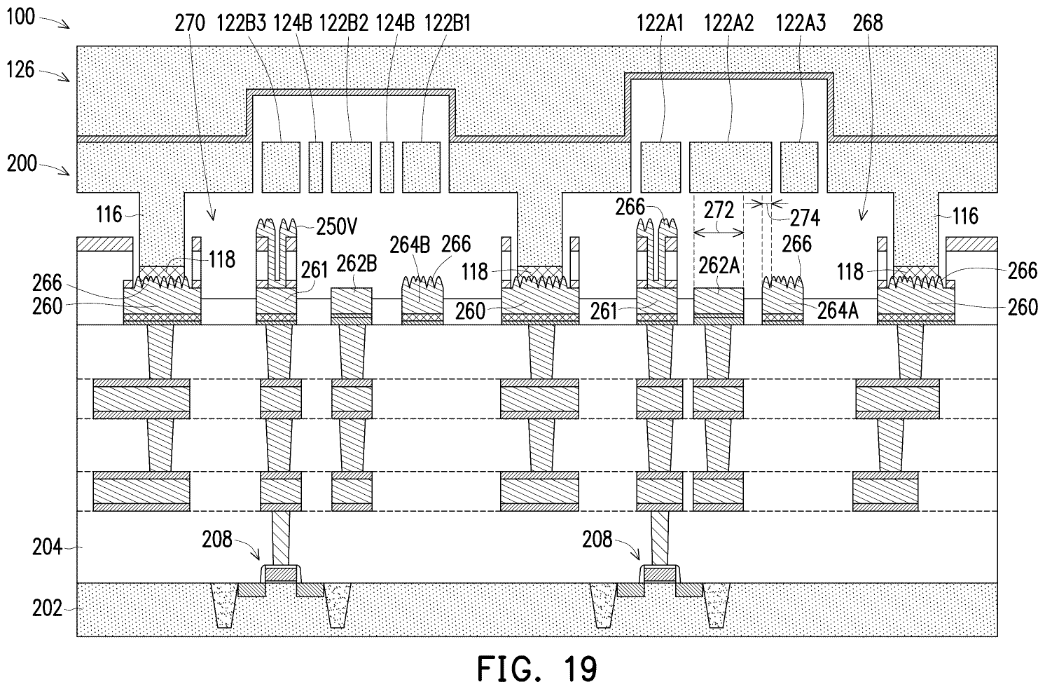

Referring to FIG. 18, a thermal process is performed to form hillocks 266 on the bond pads 260, the dummy pads 264A, 264B, and the vias 250V, in accordance with some embodiments. The hillocks 266 may be randomly distributed on the surfaces of the bond pads 260, the dummy pads 264A, 264B, and the vias 250V. In some embodiments, the hillocks 266 have a height of about 0.1 μm to 2 μm, such as 0.6 μm to 1 μm, depending on the desired increase in surface roughness. The thermal process may be an anneal process, a thermal process for forming an alloy, a bonding process, a baking process, a reflow process, or some other thermal process. The hillocks 266 are formed in the aluminum copper material of the metal fill layer 236 when the underlying barrier layers include the barrier layer 228 (titanium) and the barrier layer 232 (titanium nitride) due to compressive stress induced by the different materials of the barrier layers 228, 232. However, the formation of hillocks 266 is suppressed on the sensing pads 262A, 262B with the barrier layers 224, 228 (titanium) since the compressive stress is absent. The hillocks 266 may be substantially aluminum. In some embodiments, the hillocks 266 have a domed shape, such as trapezoidal vertical cross-section. The corners of the hillocks 266 may be rounded. The horizontal cross-section shape of the hillocks 266 at the interface with the metal fill layer 236 may be circular or polygonal, such as an oval, a triangle, a diamond, a pentagon, a hexagon, or some other shape. The size of the hillocks 266 are exaggerated in FIG. 18 for illustration purposes. The hillocks 266 increase the surface roughness of the bond pads 260, the dummy pads 264A, 264B, and the vias 250V.

Referring to FIG. 19, the MEMS structure 126 is bonded to the device die 200, in accordance with some embodiments. For ease of illustration, not all elements of the MEMS structure 126 and the device die 200 are numbered. In some embodiments, heat and/or pressure is applied to bond the MEMS structure 126 to the device die 200. Bonding the MEMS structure 126 to the device die 200 defines sensing cavities 268, 270 defined by the semiconductor layer 102, the bonding layer 108, the semiconductor layer 110, and the uppermost interlayer dielectric layer 204 that encapsulate the MEMS elements 128, 130. The sensing pad 262A is under and at least partially horizontally overlapping the movable MEMS element 122A2 as indicated by a horizontal overlap line 272. The dummy pad 264A is also under and at least partially horizontally overlapping the movable MEMS element 122A2 as indicated by a horizontal overlap line 274. The device die 200 may be part of a semiconductor wafer that includes multiple device dies. At a later point in the production flow, the device wafer may be singulated to separate the device die 200 and the attached MEMS structure 126 into a single package.

In some embodiments, uppermost portions of the bond pads 260 comprise a eutectic material, such as AlCu, that bonds with the bond pads 118 over the stand-off features 116 of the MEMS structure 126. A eutectic material is an alloy having a temperature where the constituents of the alloy melt at the same temperature and at a temperature lower than the melting point of any of its constituents. During the bonding of the MEMS structure 126 to the device die 200, the large grain of the bond pads 260 resulting from the hillocks 266 improves the quality of the bond. In some embodiments, the increased bond quality allows a reduction in the pressure applied during the bonding process, reducing the likelihood or warping, damage, or wafer breakage.

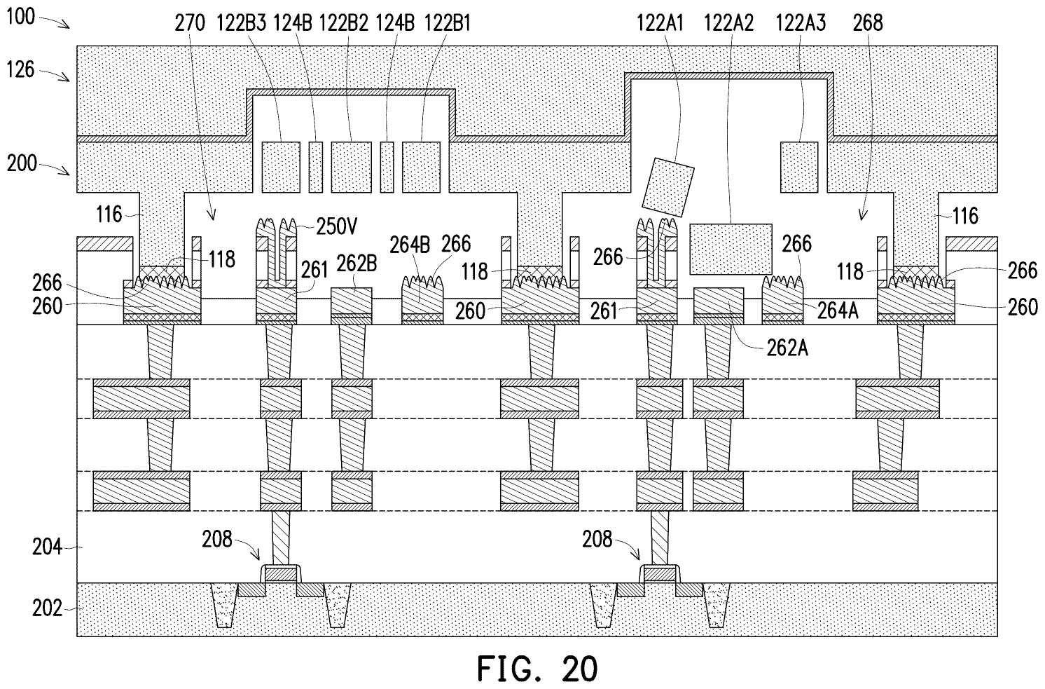

Referring to FIG. 20, the movable MEMS elements 122A1, 122A2, 122A3, 122B1, 122B2, 122B3 may move within the cavities 268, 270 to perform the sensing function of the MEMS structure 126. When an applied force causes movement of the movable MEMS element 122A2, the movement is sensed by the sensing pad 262A. If the force deflects the movable MEMS element 122A2 toward the sensing pad 262A, the movable MEMS element 122A2 will contact the dummy pad 264A prior to contacting the sensing pad 262A, thereby protecting the sensing pad 262A from being damaged. The increased surface roughness provided by the hillocks 266 on the dummy pad 264A reduces the likelihood that the movable MEMS element 122A2 will adhere to the dummy pad 264A if contact occurs, thereby reducing the possibility of damaging the sensing ability of the MEMS structure 126.

In some embodiments, the devices 208 are portions of a circuit implemented by the semiconductor structure 100 for sensing using the MEMS structure 126. The devices 208 may be connected to a charge release path through the vias 250V. Additional devices 208 may be provided connected to the sensing pads 262A, 262B. The circuit may comprises a sensor circuit comprising at least one of an image sensor, a complementary metal-oxide-semiconductor (CMOS) image sensor (CIS), a backside CIS, a proximity sensor, a time of flight (ToF) sensor, an indirect ToF (iToF) sensor, a backside illumination (BSI) sensor, or some other type of sensor. In some embodiments, the circuit comprises a logic circuit, a light-emitting diode (LED) circuit, a liquid-crystal display (LCD) circuit, a random access memory (RAM) circuit, or other type of circuit. Other structures and/or configurations of the semiconductor structure 100 are within the scope of the present disclosure.

According to some embodiments, a semiconductor structure includes a semiconductor layer, a micro-electromechanical systems structure defined in the semiconductor layer, and a metallization structure bonded to the semiconductor layer. The metallization structure includes a sensing pad, a first barrier layer comprising a first material under the sensing pad, a conductive pad, and a second barrier layer under the conductive pad. The second barrier layer includes a first layer comprising the first material and a second layer comprising a second material different than the first material over the first layer. The second barrier layer is compressively stressed, and hillocks are defined in the conductive pad.

According to some embodiments, a semiconductor structure includes a semiconductor layer, a micro-electromechanical systems structure comprising a moveable element defined in the semiconductor layer, and a metallization structure bonded to the semiconductor layer. The metallization structure includes a sensing pad under and at least partially horizontally overlapping the moveable element, a dummy pad under and at least partially horizontally overlapping the moveable element, and hillocks defined in the dummy pad. A first spacing between the moveable element and the dummy pad is less than a second spacing between the moveable element and the sensing pad.

According to some embodiments, a method for forming a semiconductor structure includes forming a first barrier layer comprising a first material over a dielectric layer of a metallization structure, forming a second barrier layer comprising a second material different than the first material over the first barrier layer, and removing a portion of the second barrier layer in a sensing pad region. A conductive layer is formed over the first barrier layer and the second barrier layer. The conductive layer is patterned to define a sensing pad in the sensing pad region over the first barrier layer and a conductive pad over the second barrier layer. A thermal process is performed to form hillocks in the conductive pad. A micro-electromechanical systems structure including a moveable element in a semiconductor layer is formed. The micro-electromechanical systems structure is attached to the metallization structure. The moveable element is over and at least partially horizontally overlapping the sensing pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor structure, comprising:
a semiconductor layer;
a micro-electromechanical systems structure defined in the semiconductor layer; and
a metallization structure bonded to the semiconductor layer, the metallization structure comprising:
a sensing pad;
a first barrier layer comprising a first material under the sensing pad;
a conductive pad; and
a second barrier layer under the conductive pad, the second barrier layer comprising:
a first layer comprising the first material; and
a second layer comprising a second material different than the first material over the first layer, wherein:
the second barrier layer is compressively stressed, and
hillocks are defined in the conductive pad.

2. The semiconductor structure of claim 1, comprising:
a stand-off feature defined in the semiconductor layer, wherein the conductive pad comprises a first bond pad connected to the stand-off feature.

3. The semiconductor structure of claim 2, comprising:
a second bond pad on the stand-off feature, wherein the second bond pad is bonded to the first bond pad.

4. The semiconductor structure of claim 1, wherein:
the conductive pad comprises:
a conductive layer over the second barrier layer;
a passivation layer over the conductive layer; and
a conductive via in the passivation layer and connected to the conductive layer, and
the hillocks are defined in the conductive via.

5. The semiconductor structure of claim 4, comprising:
a third barrier layer over the conductive layer, the third barrier layer comprising:
a third layer comprising the first material; and
a fourth layer comprising the second material over the third layer.

6. The semiconductor structure of claim 1, wherein:
the micro-electromechanical systems structure comprises a moveable element,
the sensing pad is under and at least partially overlapping the moveable element, and
the conductive pad comprises a dummy pad under and at least partially overlapping the moveable element.

7. The semiconductor structure of claim 1, wherein:
the first material comprises titanium, and
the second material comprises titanium nitride.

8. The semiconductor structure of claim 1, wherein:
the sensing pad comprises a eutectic material, and
the conductive pad comprises the eutectic material.

9. A semiconductor structure, comprising:
a semiconductor layer;
a micro-electromechanical systems structure comprising a moveable element defined in the semiconductor layer; and
a metallization structure bonded to the semiconductor layer, the metallization structure comprising:
a sensing pad under and at least partially horizontally overlapping the moveable element;
a dummy pad under and at least partially horizontally overlapping the moveable element; and
hillocks defined in the dummy pad, wherein a first spacing between the moveable element and the dummy pad is less than a second spacing between the moveable element and the sensing pad.

10. The semiconductor structure of claim 9, comprising:
a first barrier layer comprising a first material under the sensing pad; and
a second barrier layer under the dummy pad and comprising:
a first layer comprising the first material; and
a second layer comprising a second material different than the first material over the first layer, wherein the second barrier layer is compressively stressed.

11. The semiconductor structure of claim 10, comprising:
a stand-off feature defined in the semiconductor layer;
a bond pad in the metallization structure connected to the stand-off feature; and
a third barrier layer under the bond pad, the third barrier layer comprising:
a third layer comprising the first material; and
a fourth layer comprising the second material over the third layer, wherein second hillocks are defined in the bond pad.

12. The semiconductor structure of claim 10, wherein the metallization structure comprises:
a conductive layer;
a passivation layer over the conductive layer;
a conductive via in the passivation layer and connected to the conductive layer; and
a third barrier layer under the conductive layer, the third barrier layer comprising:
a third layer comprising the first material; and
a fourth layer comprising the second material over the third layer, wherein second hillocks are defined in the conductive via.

13. The semiconductor structure of claim 12, comprising:
a fourth barrier layer over the conductive layer and under the passivation layer, the fourth barrier layer comprising:
a fifth layer comprising the first material; and
a sixth layer comprising the second material over the fifth layer.

14. The semiconductor structure of claim 10, wherein:
the first material comprises titanium, and
the second material comprises titanium nitride.

15. The semiconductor structure of claim 9, wherein:
the sensing pad comprises a eutectic material, and
the dummy pad comprises the eutectic material.

16. A method for forming a semiconductor structure, comprising:
forming a first barrier layer comprising a first material over a dielectric layer of a metallization structure;
forming a second barrier layer comprising a second material different than the first material over the first barrier layer;
removing a portion of the second barrier layer in a sensing pad region;
forming a conductive layer over the first barrier layer and the second barrier layer;
patterning the conductive layer to define a sensing pad in the sensing pad region over the first barrier layer and a conductive pad over the second barrier layer;
performing a thermal process to form hillocks in the conductive pad;
forming a micro-electromechanical systems structure comprising a moveable element in a semiconductor layer; and
attaching the micro-electromechanical systems structure to the metallization structure, wherein the moveable element is over and at least partially horizontally overlapping the sensing pad.

17. The method of claim 16, comprising:
forming a stand-off feature in the semiconductor layer; and
forming a first bond pad on the stand-off feature, wherein:
the conductive pad comprises a second bond pad, and
attaching the micro-electromechanical systems structure to the metallization structure comprises attaching the first bond pad to the second bond pad.

18. The method of claim 16, comprising:
patterning the conductive layer to define a base pad;
forming a passivation layer over the base pad; and
forming a conductive via in the passivation layer and connected to the base pad, wherein:
the conductive pad comprises the base pad and the conductive via, and
the hillocks are defined in the conductive via.

19. The method of claim 16, comprising:
patterning the conductive layer to define the conductive pad comprises patterning the conductive layer to define a dummy pad, wherein the dummy pad is under and at least partially overlapping the moveable element.

20. The method of claim 16, wherein:
forming the first barrier layer comprises forming a titanium layer,
forming the second barrier layer comprises forming a titanium nitride layer, and
portions of the second barrier layer over the first barrier layer are compressively stressed.
